(19) United States
(12) Patent Application Publication
(10) Pub. No.: US 2010/0108120 A1
(43) Pub. Date: May 6, 2010

(54) MULTI-STAGE FOLDING PORTABLE SOLAR CHARGING APPARATUS

(76) Inventors: Kuo-Len LIN, Wugu Township (TW); Chen-Hsiang Lin, Wugu Township (TW); Hwai-Ming Wang, Wugu Township (TW); Ken Hsu, Wugu Township (TW); Chih-Hung Cheng, Wugu Township (TW)

Correspondence Address: HDLS Patent & Trademark Services, P.O. BOX 220746, CHANTILLY, VA, 20153-0746, US

(21) Appl. No.: 12/265,857

(22) Filed: Nov. 6, 2008

(51) Int. Cl. H01L 31/042

(52) U.S. Cl. 136/245

(57) ABSTRACT

A multi-stage folding portable solar charging apparatus includes first, second and third photoelectric conversion modules. The second photoelectric conversion module is pivotally connected to a side of the first photoelectric conversion module and folded/unfolded with respect to an upper surface of the first photoelectric conversion module, and the third photoelectric conversion module is pivotally connected to another side of the first photoelectric conversion module and can be folded/unfolded with respect to a lower surface of the first photoelectric conversion module, such that the photoelectric conversion modules are electrically connected with each other. A connector is fixed and electrically connected to one of the photoelectric conversion modules. The second and third photoelectric conversion modules are unfolded from the stacked first photoelectric conversion module to increase an electric power generation area of charging apparatus when unfolded to enhance the electric power generation, and reduce the volume of the charging apparatus when folded.

### BACKGROUND OF THE INVENTION

1. Field of the Invention

The present invention generally relates to a solar charging apparatus, and more particularly to a multi-stage folding portable solar charging apparatus.

2. Description of Prior Art

At present, solar power generation technologies are used extensively in our daily life, and portable solar charging apparatuses are applied commonly in portable electronic devices such as mobile phones and personal digital assistants (PDA).

A traditional portable solar charging apparatus applied in a portable electronic device generally includes a body, a circuit board, a connector and a solar power generation unit, and the circuit board is installed in the body, and the connector is connected to an end of the body and electrically coupled to the circuit board, and the solar power generation unit is generally a sheet attached onto a distal surface of the body and electrically coupled to the circuit board.

When the traditional portable solar charging apparatus is used, the charging device is placed under sunlight, and the connector is plugged into a power slot of the portable electronic device for charging the portable electronic device.

However, the aforementioned traditional portable solar charging apparatus still has the following drawbacks. In a convenient portable design, the length, width and thickness of the body are generally not too large, or else the volume of the body will be too large and inconvenient to carry. However, if the surface area of the body is not large enough, the body can attach a limited number of solar power generation units only, and thus the solar charging apparatus has a too-small electric power generation area, and the electric power generation efficiency cannot be improved.

Therefore, some manufacturers introduced a folding portable solar charging apparatus to the market, and the body of such solar charging apparatus can be folded to increase the electric power generation area of the apparatus. However, the increase of electric power generation area of this structure is still very limited, and the electric power generation efficiency of this solar charging apparatus cannot be improved effectively.

Finding a way to improve and overcome the foregoing drawbacks is the subject of this invention.

### SUMMARY OF THE INVENTION

It is a primary objective of the present invention to provide a multi-stage folding portable solar charging apparatus, wherein a second photoelectric conversion module and a third photoelectric conversion module can be folded and unfolded with respect to the first photoelectric conversion module to increase the electric power generation area of the solar charging apparatus when unfolded, so as to improve the power generation effect.

Another objective of the present invention is to provide a multi-stage folding portable solar charging apparatus, wherein a second photoelectric conversion module and a third photoelectric conversion module can be folded onto the top and the bottom of a first photoelectric conversion module to decrease the volume of the solar charging apparatus when folded.

To achieve the foregoing objectives, the present invention provides a multi-stage folding portable solar charging apparatus comprising a first photoelectric conversion module, a second photoelectric conversion module, a third photoelectric conversion module and a connector, wherein the second photoelectric conversion module is pivotally coupled to an end of the first photoelectric conversion module and can be folded or unfolded with respect to an upper surface of the first photoelectric conversion module, and the third photoelectric conversion module is pivotally coupled to another side of the first photoelectric conversion module and can be folded or unfolded with respect to a lower surface of the first photoelectric conversion module, and the photoelectric conversion modules are electrically coupled with each other, and the connector is fixed and electrically coupled to one of the photoelectric conversion modules.

Another objective of the present invention is to provide a multi-stage folding portable solar charging apparatus, wherein the connector is a USB connector used for improving the applicability and practicability of the solar charging apparatus.

### BRIEF DESCRIPTION OF DRAWINGS

FIG. 1 is a perspective view of the invention;

FIG. 2 is a perspective view of operations of the invention;

FIG. 3 is a perspective view of another form of the invention;

FIG. 4 is a schematic view of the invention applied in a portable electronic device;

FIG. 5 is a perspective view of another preferred embodiment of the invention;

FIG. 6 is a side view of operation of another preferred embodiment of the invention; and

FIG. 7 a schematic view of another preferred embodiment of the invention applied in a portable electronic device.

### DETAILED DESCRIPTION OF THE INVENTION

The technical characteristics, features and advantages of the present invention will become apparent in the following detailed description of preferred embodiments with reference to the accompanying drawings, and the preferred embodiments are used for illustrating the present invention only, but not intended to limit the scope of the invention.

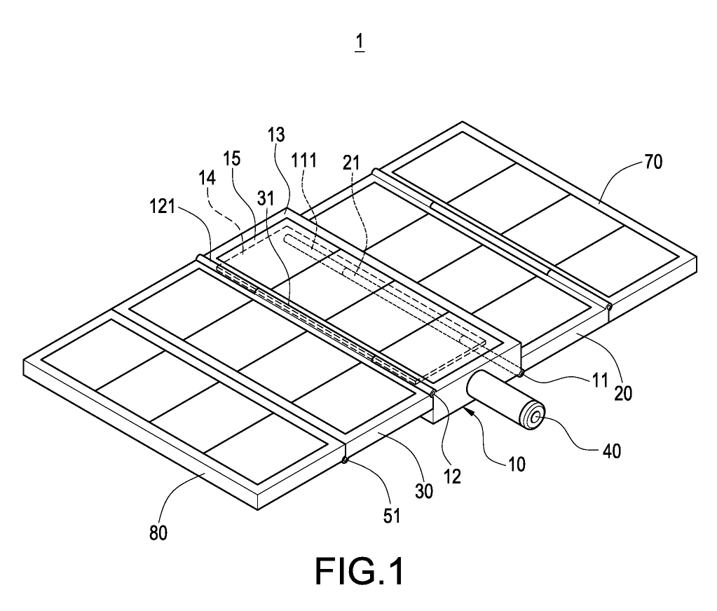

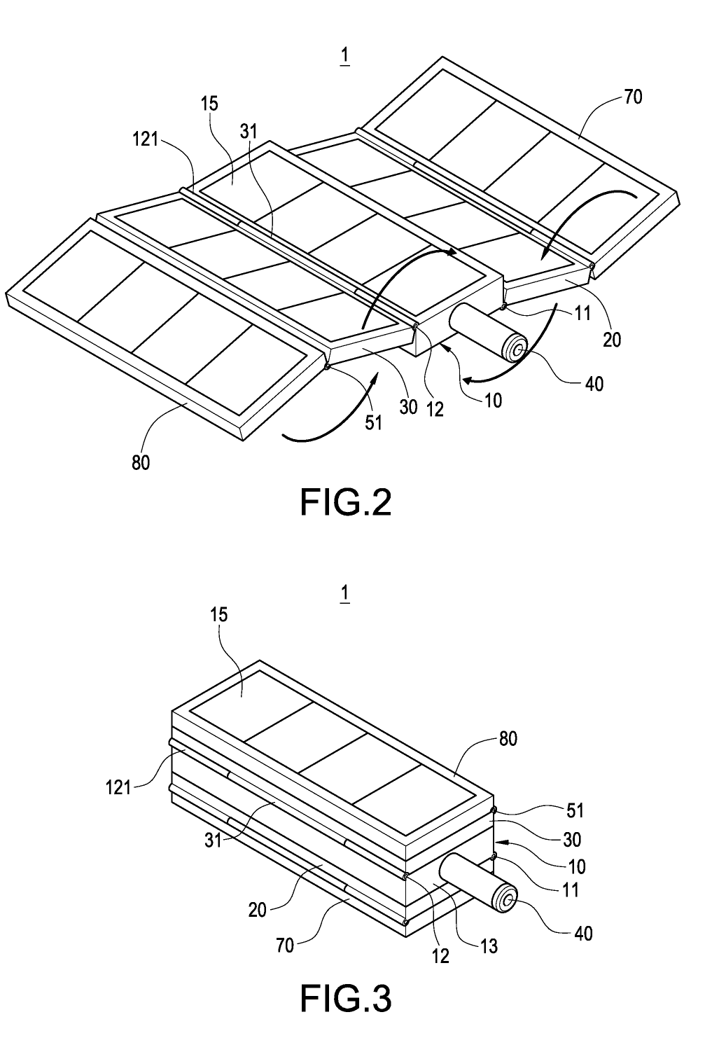

With reference to FIGS. 1 to 3 for a perspective view of the invention, a perspective view of operations of the invention, and a perspective view of another form of the invention respectively, the invention provides a multi-stage folding portable solar charging apparatus comprising a first photoelectric conversion module 10, a second photoelectric conversion module 20, a third photoelectric conversion module 30 and a connector 40.

The first photoelectric conversion module 10 forms a first pivoting section 11 and a second pivoting section 12 on both ends of the first photoelectric conversion module 10 respectively, and the first pivoting section 11 and the second pivoting section 12 are disposed at corresponding diagonally opposite positions, and the photoelectric conversion module 10 includes a body 13, a circuit board 14 installed in the body 13 and a solar power generation unit 15 attached onto a surface of the body 13 and electrically coupled to the circuit board 14.

The second photoelectric conversion module 20 is pivotally coupled to a side of the first 10 photoelectric conversion module 10 and can be folded or unfolded with respect to an upper surface of the first photoelectric conversion module 10. Further, the second photoelectric conversion module 20 is pivotally coupled to the first pivoting section 11.

The third photoelectric conversion module 30 is pivotally coupled to another side of the first photoelectric conversion module 10 and can be folded or unfolded with respect to a lower surface of the first photoelectric conversion module 10. Further, the third photoelectric conversion module 30 is pivotally coupled to the second pivoting section 12, and the photoelectric conversion modules 10, 20, 30 are electrically coupled with each other, and the connector 40 is electrically coupled to one of the photoelectric conversion modules 10, 20, 30. In this preferred embodiment, the connector is electrically coupled to the first photoelectric conversion module 10.

Each of the first pivoting section 11 and the second pivoting section 12 forms a first protruding ear 111, 121, and the second photoelectric conversion module 20 forms a second protruding ear 21 corresponding to the first protruding ear 111, and the third photoelectric conversion module 30 forms a first protruding ear 111 and a second protruding ear 31 corresponding to the first protruding ear 121, and the second protruding ear 21 is provided for passing a pivotal shaft 51, and the first protruding ear 121 and the second protruding ear 31 are provided for passing a pivotal shaft 51.

The second photoelectric conversion module 20 and the third photoelectric conversion module 30 can be rotated with respect to the first photoelectric conversion module 10 and stacked onto the first photoelectric conversion module 10, so as to increase the electric power generation area of the solar charging apparatus 1 when unfolded, and also improve the electric power generation. The second photoelectric conversion module 20 and the third photoelectric conversion module 30 can be folded onto the top and the bottom of the first photoelectric conversion module 10 respectively to reduce the volume of the solar charging apparatus 1 when folded. When the second photoelectric conversion module 20 and the third photoelectric 10 conversion module 30 are folded as shown in FIG. 3, only the thickness of the solar charging apparatus 1 is increased, but the volume is reduced significantly.

The solar charging apparatus 1 further comprises a fourth photoelectric conversion module 70 and a fifth photoelectric conversion module 80, and the fourth photoelectric conversion module 70 is pivotally coupled to the second photoelectric conversion module 20, and the fifth photoelectric conversion module 80 is pivotally coupled to the third photoelectric conversion module 30. The pivoting position of the fourth photoelectric conversion module 70 and the second photoelectric conversion module 20 and the pivoting position of the second photoelectric conversion module 20 and the first photoelectric conversion module 10 are disposed at corresponding diagonally opposite positions. The pivoting position of the fifth photoelectric conversion module 80 and the third photoelectric conversion module 30 and the pivoting position of the third photoelectric conversion module 30 and the first photoelectric conversion module 10 are disposed at corresponding diagonally opposite positions

The solar power generation units 15 of the photoelectric conversion module 10, 20, 30, 70 and 80 are disposed on a same surface of the photoelectric conversion module 10, 20, 30, 70 and 80 when unfolded.

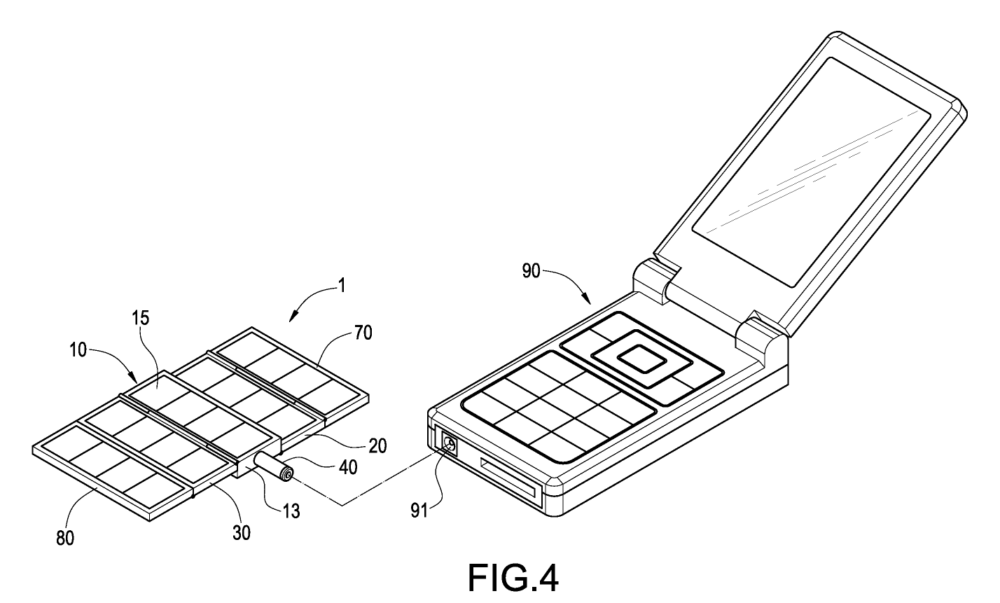

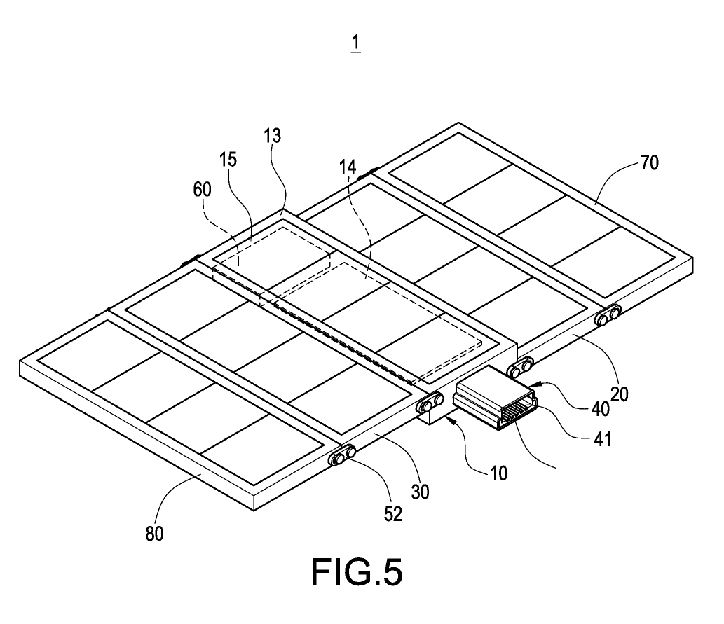

With reference to FIG. 4 for a preferred embodiment to the present invention applied in a portable electronic device 90 including but not limited to a mobile phone and a personal digital assistant (PDA), the electronic device 90 includes a power input slot 91 corresponding to the connector 40. When the solar charging apparatus 1 is used, the photoelectric conversion modules 10, 20, 30, 70, 80 are unfolded, and the connector 40 is plugged into the power input slot 91 of the electronic device 90 for charging the electronic device 90.

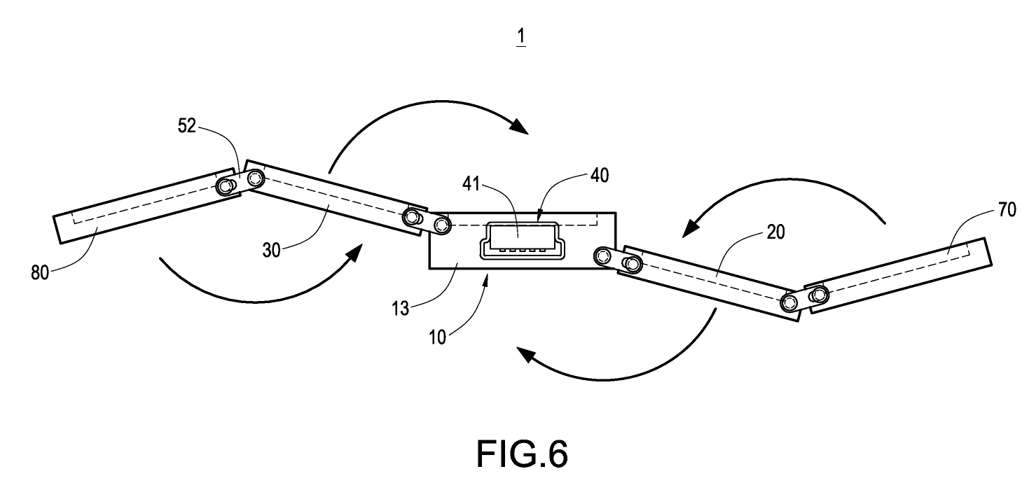

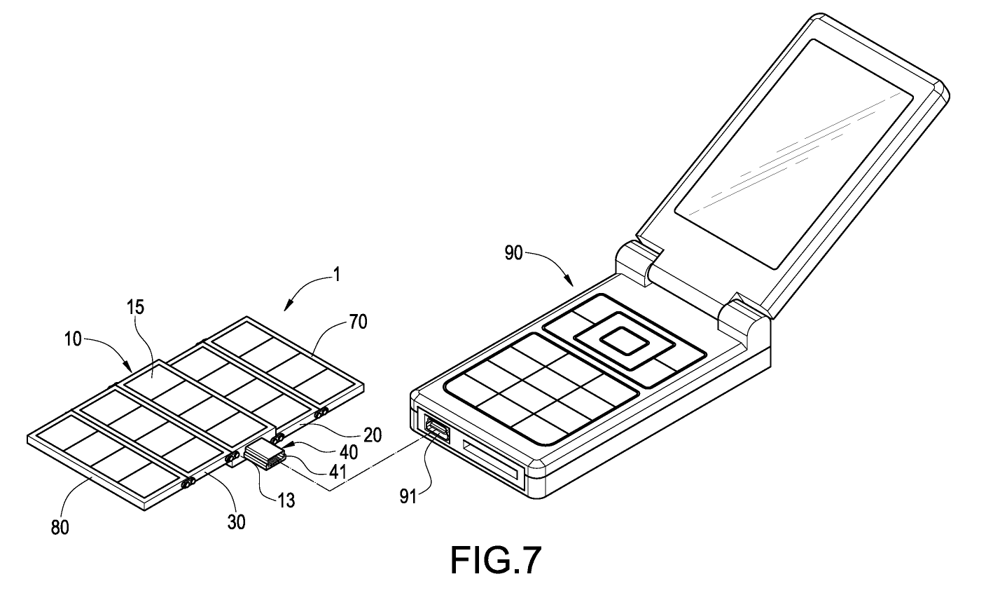

With reference to FIGS. 5 to 7 for a perspective view, a side view of operations, and a schematic view of the invention applied to a portable electronic device in accordance with another preferred embodiment of the present invention respectively, the photoelectric conversion modules 10, 20, 30, 70, 80 are pivotally coupled by a plurality of hinges 72, such that the photoelectric conversion modules 20, 30, 70, 80 can be folded or unfolded with respect to the first photoelectric conversion module 10.

The solar charging apparatus 1 further comprises a cell 60 installed in one of the photoelectric conversion modules 10, 20, 30, 70, 80 and electrically coupled to the photoelectric conversion modules 10, 20, 30, 70, 80 and the connector 40. With the installed cell 60, the solar charging apparatus 1 can convert light energy into electric energy to be stored in the cell 60 first, and then stored into the electronic device 90 through the connector 40.

In this preferred embodiment, the connector 40 is a USB connector 41 that can be used in different electronic devices 90, and the type of the connector 40 is not limited to any particular type but depends on the electronic device 90.

In summation of the description above, the invention complies with patent application requirements, and is duly filed for patent application. While the invention has been described by means of specific embodiments, numerous modifications and variations could be made thereto by those skilled in the art without departing from the scope and spirit of the invention set forth in the claims.

What is claimed is:

1. A multi-stage folding portable solar charging apparatus, comprising:
a first photoelectric conversion module;
a second photoelectric conversion module, pivotally coupled to a side of the first photoelectric conversion module, and foldable/unfoldable with respect to an upper distal surface of the first photoelectric conversion module;
a third photoelectric conversion module, pivotally coupled to another side of the first photoelectric conversion module, and foldable/unfoldable with respect to a lower distal surface of the first photoelectric conversion module, such that the first, the second and the third photoelectric conversion modules are electrically coupled with each other; and
a connector, fixed and electrically coupled to one of the first, the second and the third photoelectric conversion modules.

2. The multi-stage folding portable solar charging apparatus of claim 1, wherein the first photoelectric conversion module includes a first pivoting section and a second pivoting section formed on both sides of the first photoelectric conversion module respectively, and the first pivoting section and the second pivoting section are disposed at corresponding diagonally opposite positions, and the second photoelectric conversion module is pivotally coupled to the first pivoting section, and the third photoelectric conversion module is pivotally coupled to the second pivoting section.

3. The multi-stage folding portable solar charging apparatus of claim 2, wherein each of the first pivoting section and the second pivoting section forms a first protruding ear, and each of the second photoelectric conversion module and the third photoelectric conversion module forms a second protruding ear of the first protruding ear, and the first protruding ear and the second protruding ear are provided for passing and connecting a pivotal shaft.

4. The multi-stage folding portable solar charging apparatus of claim 1, wherein each of the first, the second and the third photoelectric conversion modules includes a body, a circuit board installed in the body, and a solar power generation unit attached on a surface of the body and electrically coupled to the circuit board.

5. The multi-stage folding portable solar charging apparatus of claim 4, further comprising a fourth photoelectric conversion module and a fifth photoelectric conversion module, and the fourth photoelectric conversion module is pivotally coupled to the second photoelectric conversion module, and the fifth photoelectric conversion module is pivotally coupled to the third photoelectric conversion module.

6. The multi-stage folding portable solar charging apparatus of claim 5, wherein the pivoting position of the fourth photoelectric conversion module and the second photoelectric conversion module and the pivoting position of the second photoelectric conversion module and the first photoelectric conversion module are disposed at corresponding diagonally opposite positions, and the pivoting position of the fifth photoelectric conversion module and the third photoelectric conversion module and the pivoting position of the third photoelectric conversion module and the first photoelectric conversion module are disposed at corresponding diagonally opposite positions.

7. The multi-stage folding portable solar charging apparatus of claim 6, wherein the solar power generation units of the first, the second, the third, the fourth and the fifth photoelectric conversion modules are disposed on a same surface when the photoelectric conversion modules is unfolded.

8. The multi-stage folding portable solar charging apparatus of claim 1, wherein the first, the second and the third photoelectric conversion modules are pivotally coupled with each other by a plurality of hinges.

9. The multi-stage folding portable solar charging apparatus of claim 1, wherein the connector is a USB connector.

10. The multi-stage folding portable solar charging apparatus of claim 1, further comprising a cell installed at one of the first, the second and the third photoelectric conversion modules and electrically coupled to the first, the second and the third photoelectric conversion modules and the connector.
